(19) United States
(12) Patent Application Publication
(10) Pub. No.: US 2022/0131035 A1
(43) Pub. Date: Apr. 28, 2022

(54) LIGHT SOURCE USING PHOTONIC CRYSTAL STRUCTURE

(71) Applicant: University-Industry Cooperation Group of Kyung Hee University, Yongin-si, Gyeonggi-do (KR)

(72) Inventor: Youngduck KIM, Seongnam-si (KR)

(73) Assignee: University-Industry Cooperation Group of Kyung Hee University, Yongin-si, Gyeonggi-do (KR)

(21) Appl. No.: 17/296,373

(22) PCT Filed: Dec. 9, 2020
(86) PCT No.: PCT/KR2020/017939

§ 371 Date: May 24, 2021

(30) Foreign Application Priority Data
Dec. 27, 2019 (KR) 10-2019-0176539

(51) Int. Cl. H01L 33/16; H01L 33/52; H01L 33/38; H01L 33/12

(52) U.S. Cl. CPC H01L 33/16; H01L 33/12; H01L 33/387; H01L 33/52

(57) ABSTRACT

The inventive concept includes a substrate, a heterojunction structure including a first encapsulation layer, a graphene layer, and a second encapsulation layer sequentially stacked on the substrate, photonic crystal holes vertically penetrating the first encapsulation layer, the graphene layer, and the second encapsulation layer, and first and second electrodes respectively connected to both end portions of the heterojunction structure, The heterojunction structure includes buffer areas contacting the first and second electrodes, respectively, and emission areas between the buffer areas, The photonic crystal holes are provided in the emission area, and the width of the emission area is smaller than the widths of the buffer areas to provide a light source using a photonic crystal structure. In addition, a light source using the photonic crystal structure may be utilized as a photodetector.

### TECHNICAL FIELD

The present disclosure relates to a light source using a photonic crystal structure, and more specifically, to a light source using a photonic crystal structure formed in a van der Waals heterojunction structure.

### BACKGROUND ART

In a broad sense, a photonic crystal structure refers to a structure that affects the motion of a photon so that the optical properties of a material may be used. In addition, in a narrow sense, the photonic crystal structure may mean a structure that uses the optical properties of a material through a periodic optical nanostructure, and this periodic structure may be formed in 1D, 2D or 3D. The photonic crystal structure may be used in various technologies that need to confine or manipulate light, and various studies are being conducted to utilize the photonic crystal structure for optical modulation, light detection, or optical communication.

In addition, unlike the conventional light emitting diode (LED) using the band structure characteristics of the material, the luminescence mechanism of a graphene light source is based on blackbody radiation by hot electrons. In general, blackbody radiation has a very wide spectrum of wavelengths from visible light to infrared light, so that its luminous efficiency is low and there is a limit to its application to optical communication technology.

### DISCLOSURE OF THE INVENTION

### Technical Problem

The present disclosure is to provide a light source using a photonic crystal structure capable of controlling a spatial light emitting area and a light emitting wavelength.

The problem to be solved by the present disclosure is not limited to the problems mentioned above, and other tasks that are not mentioned will be clearly understood by those of ordinary skill in the relevant technical field from the following description.

### Technical Solution

In order to solve the above technical problems, a light source using the photonic crystal structure according to the embodiment of the inventive concept includes a substrate; a heterojunction structure including a first encapsulation layer, a graphene layer, and a second encapsulation layer sequentially stacked on the substrate; photonic crystal holes vertically penetrating the first encapsulation layer, the graphene layer, and the second encapsulation layer; and first and second electrodes respectively connected to both end portions of the heterojunction structure, wherein the heterojunction structure comprises buffer areas contacting the first and second electrodes, respectively, and emission areas between the buffer areas, wherein the photonic crystal holes are provided in the emission area, wherein a width of the emission area is smaller than widths of the buffer areas.

In addition, a light source using the photonic crystal structure according to the embodiment of the inventive concept includes: a substrate; a heterojunction structure including a first encapsulation layer, a graphene layer, and a second encapsulation layer sequentially stacked on the substrate; photonic crystal holes vertically penetrating the first encapsulation layer, the graphene layer, and the second encapsulation layer; and first and second electrodes respectively connected to both end portions of the heterojunction structure, wherein the heterojunction structure comprises a first area in which the photonic crystal holes are not provided and a second area surrounding the first area, the second area in which the photonic crystal holes are regularly arranged.

### Advantageous Effects

The light source using the photonic crystal structure according to the embodiment of the inventive concept may cause a strong light-material interaction at the heterojunction interface using the photonic crystal structure formed in the van der Waals heterojunction structure, so that a high quality value (Q-factor) may be maintained.

In addition, the light source using the photonic crystal structure according to the embodiment of the inventive concept may adjust the spatial light emitting area and the light emission wavelength through the modification of the photonic crystal structure, so that energy efficiency may be further increased.

### BRIEF DESCRIPTION OF THE DRAWINGS

FIG. 1 is a perspective view illustrating a structure of a light source using a photonic crystal structure according to an embodiment of the inventive concept.

FIGS. 2 and 3 are cross-sectional views illustrating a structure of a light source using a photonic crystal structure according to an embodiment of the inventive concept, and correspond to cross-sectional views of FIG. 1 taken along line I-I′.

FIGS. 4a and 5a are plan views illustrating an emission area of a light source using a photonic crystal structure according to an embodiment of the inventive concept.

FIGS. 4b and 5b are graphs for explaining the result of simulation of resonance frequency of a light source using a photonic crystal structure according to an embodiment of the inventive concept, and are results according to the photonic crystal structure of FIGS. 4a and 4b.

### MODE FOR CARRYING OUT THE INVENTION

In order to fully understand the configuration and effects of the inventive concept, preferred embodiments of the inventive concept will be described in detail with reference to the accompanying drawings.

The inventive concept is not limited to the embodiments disclosed below, but may be implemented in various forms, and various modifications and changes may be added. However, it is provided to completely disclose the technical idea of the inventive concept through the description of the present embodiments, and to fully inform a person of ordinary skill in the art to which the inventive concept belongs. In the accompanying drawings, for convenience of description, the ratio of each component may be exaggerated or reduced.

The terms used in this specification are for describing embodiments and are not intended to limit the inventive concept. In addition, terms used in the present specification may be interpreted as meanings commonly known to those of ordinary skill in the art, unless otherwise defined.

In this specification, the singular form also includes the plural form unless specifically stated in the phrase. As used in the specification, in relation to ‘comprises’ and/or ‘comprising’, the mentioned elements, steps, operations and/or elements do not exclude the presence or addition of one or more other elements, steps, operations and/or elements.

In this specification, terms such as first and second are used to describe various areas, directions, shapes, etc., but these areas, directions, and shapes should not be limited by these terms. These terms are only used to distinguish one area, direction, or shape from another area, direction, or shape. Accordingly, a portion referred to as a first portion in one embodiment may be referred to as a second portion in an embodiment. The embodiments described and illustrated herein also include complementary embodiments thereof. Like reference numerals refer to like elements throughout the specification.

Hereinafter, a light source using a photonic crystal structure according to an embodiment of the inventive concept will be described in detail with reference to the drawings.

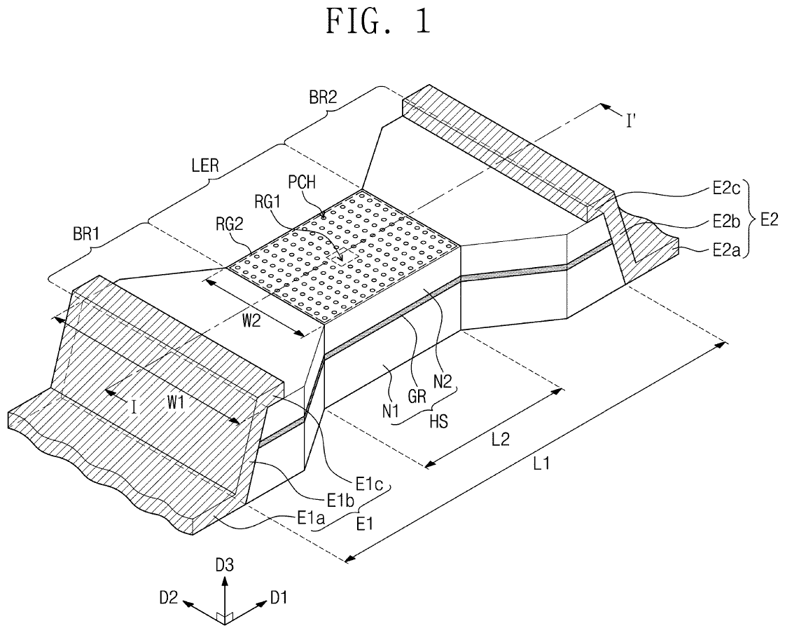

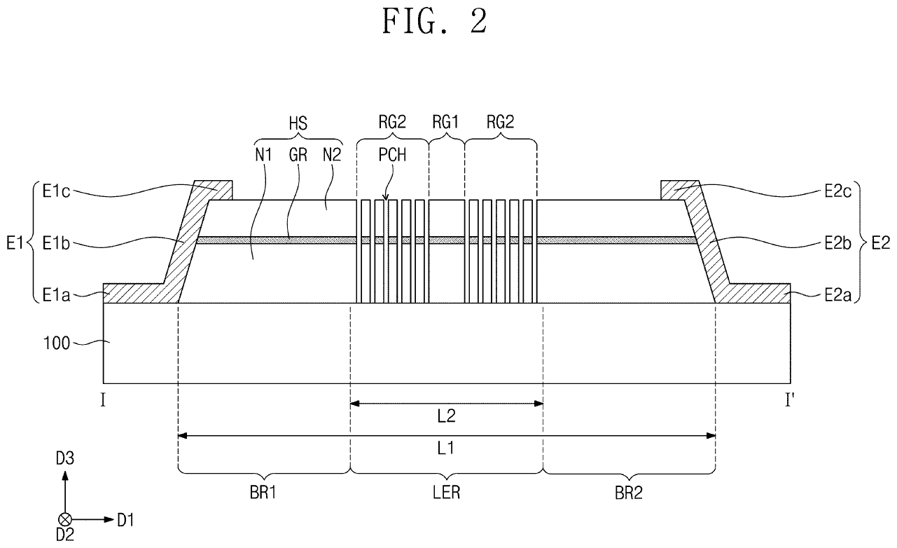

FIG. 1 is a perspective view illustrating a structure of a light source using a photonic crystal structure according to an embodiment of the inventive concept. FIG. 2 is a cross-sectional view illustrating a structure of a light source using a photonic crystal structure according to an embodiment of the inventive concept, and corresponds to a cross-sectional view of FIG. 1 taken along line I-I′.

Referring to FIGS. 1 and 2, a light source using a photonic crystal structure according to an embodiment of the inventive concept includes a first electrode E1, a second electrode E2, and a heterojunction structure HS between the first electrode E1 and the second electrode E2. The first electrode E1, the second electrode E2, and the heterojunction structure HS may be provided on the substrate 100. The substrate 100 may include, for example, silicon oxide.

The first electrode E1 may contact an end portion of the heterojunction structure HS. The first electrode E1 may contact one end portion of the heterojunction structure HS by an edge contact method, and thus, contact resistance may be minimized. More specifically, the first electrode E1 may include a first portion E1a and a third portion E1c extending in the first direction D1 and the second direction D2, and a second portion E1b connecting the first portion E1a and the third portion E1c. The first direction D1 and the second direction D2 extend on the same plane and may be perpendicular to each other. For example, the second portion E1b may extend in a direction having an inclination with respect to the third direction D3. The third direction D3 may be a direction perpendicular to the first direction D1 and the second direction D2. The second electrode E2 may contact another end portion of the heterojunction structure HS that faces one end portion in contact with the first electrode E1. The second electrode E2 may be spaced apart from each other in the first electrode E1 and in the first direction D1. More specifically, the second electrode E2 may include a first portion E2a and a third portion E2c extending in the first direction D1 and the second direction D2, and a second portion E2b connecting the first portion E2a and the third portion E2c. The first to third portions E2a, E2b, and E2c of the second electrode E2 may have substantially the same shape as the first to third portions E1a, E1b, and E1c of the first electrode E1, respectively. However, this is only an example, and the first electrode E1 and the second electrode E2 may each have various shapes electrically connected to the heterojunction structure HS. The first electrode E1 and the second electrode E2 may include metal. For example, the first electrode E1 and the second electrode E2 may include any one of chromium (Cr), palladium (Pd), and gold (Au). The first electrode E1 and the second electrode E2 may be any one of a source electrode and a drain electrode, respectively. More specifically, when the first electrode E1 is a source electrode, the second electrode E2 may be a drain electrode, and when the first electrode E1 is a drain electrode, the second electrode E2 may be a source electrode. A voltage for the operation of the heterojunction structure HS may be applied through the first electrode E1 and the second electrode E2, and a current may flow.

The voltage applied through the first electrode E1 and the second electrode E2 may be a pulse voltage or a DC voltage. When a pulse voltage is applied to the first electrode E1 and the second electrode E2, super-fast direct modulation of the light source is possible. At this time, the pulse voltage may be about 2 Volts or less. When a DC bias voltage is applied to the first electrode E1 and the second electrode E2, the resonance frequency (or wavelength) and quality value of the light source may be controlled by using thermal expansion of the heterojunction structure HS by Joule heating of the graphene layer GR. In this case, the DC bias voltage may be about 5 Volts or more.

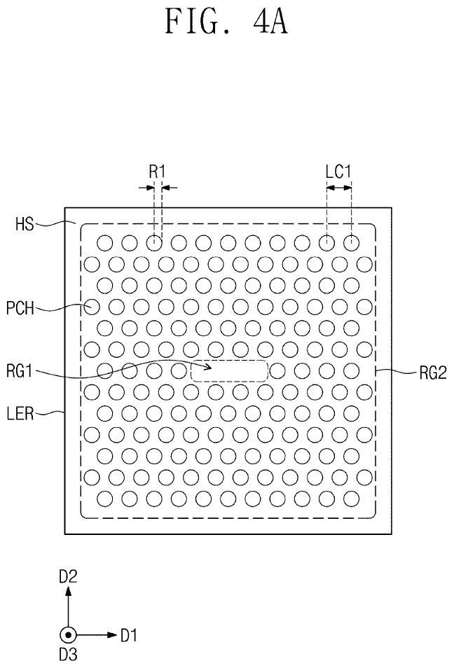

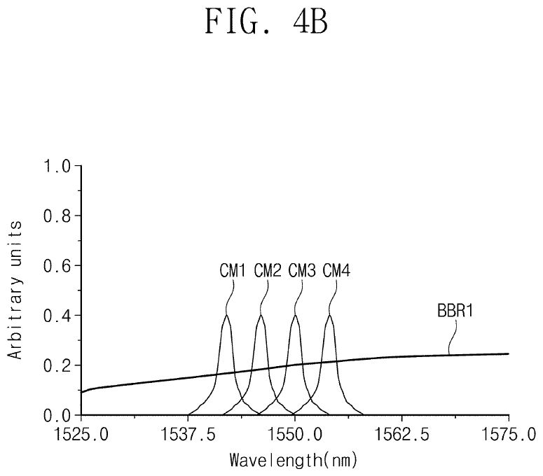

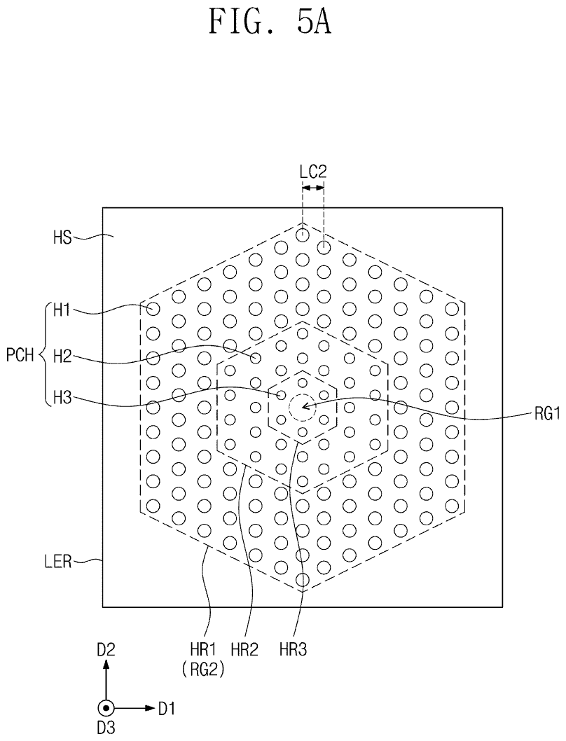

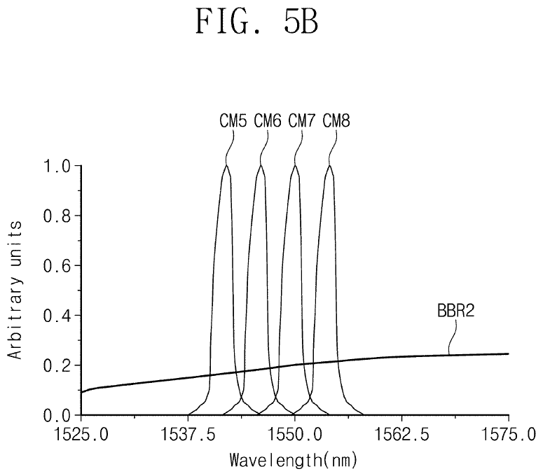

From a plan view, the heterojunction structure HS may include a first buffer area BR1, a second buffer area BR2, and an emission area LER between the first buffer area BR1 and the second buffer area BR2. Here, a photonic crystal structure including a plurality of photonic crystal holes PCH may be provided in the emission area LER. The emission area LER may include a first area RG1 in which photonic crystal holes PCH are not provided and a second area RG2 surrounding the first area RG1, the second area RG2 in which photonic crystal holes PCH are provided. The photonic crystal holes PCH may be regularly arranged in the second area RG2, and the first area RG1 may be defined as an area in which a rule in which the photonic crystal holes PCH are arranged in the second region RG2 is broken. For example, the first area RG1 may be located in the center part of the upper surface of the emission area LER. However, unlike shown in the drawing, the first area RG1 may be provided in plural, and may be located in a place other than the center part. For example, 1 to 30 first areas RG1 may be provided at different positions. By controlling the position of the first area RG1, it is possible to determine the local light emission position of the light source according to the inventive concept. The arrangement of the plurality of photonic crystal holes PCH and the location of the first area RG1 will be described in detail later with reference to FIGS. 4a and 5a. The emission area LER may be spaced apart from the first electrode E1 in the first direction D1 with the first buffer area BR1 interposed therebetween. In addition, the emission area LER may be spaced apart from the second electrode E2 in the first direction D1 with the second buffer area BR2 interposed therebetween. The first buffer area BR1 and the second buffer area BR2 may prevent heat generated in the emission area LER from being transferred to the first electrode E1 and the second electrode E2.

The maximum length of the heterojunction structure HS in the first direction D1 may be defined as the first length L1, and the maximum width of the heterojunction structure HS in the second direction D2 may be defined as the first width W1. The contact resistance between the heterojunction structure HS and the first electrode E1 and the second electrode E2 may be determined through the first width W1. For example, the first length L1 and the first width W1 may be about 2 μm to about 10 μm, respectively.

The length of the emission area LER in the first direction D1 may be defined as the second length L2, and the width of the emission area LER in the second direction D2 may be defined as the second width W2. For example, the second length L2 and the second width W2 may be about 1 μm to about 5 μm, respectively. For example, the emission area LER may have a rectangular upper surface having a constant length in the first direction D1 and a constant width in the second direction D2. The second length L2 may be smaller than the first length L1, and the second width W2 may be smaller than the first width W1. For this reason, the light source according to the inventive concept may operate stably. More specifically, since the second width W2 of the emission area LER is smaller than the first width W1, the light emission position may be localized. As the light emission position is localized, the quality value may increase, and as the quality value increases, the energy efficiency of the light source may increase. The operating current magnitude I of the light source according to the inventive concept may be proportional to the second width W2. That is, it is possible to determine the operating current magnitude I of the light source through the second width W2. The proportional relationship between the operating current magnitude I and the second width W2 of the light source according to the inventive concept may be expressed by [Equation 1].

I=W2×α [Equation 1]

In [Equation 1], I is an operating current magnitude, and α is a proportional constant. The unit of the operating current magnitude is mA, and the unit of the proportional constant α is mA/μm. For example, the proportional constant α may be about 1 to 2.

In addition, since the second length L2 of the emission area LER is smaller than the first length L1, deformation and damage of the first electrode E1 and the second electrode E2 may be reduced by joule heating of the graphene layer GR. The operating voltage magnitude V of the light source according to the inventive concept may be proportional to the second length L2. That is, the operating voltage magnitude V of the light source may be determined through the second length L2. The proportional relationship between the operating voltage magnitude V and the second length L2 of the light source according to the inventive concept may be expressed by [Equation 2].

V=L2×β [Equation 2]

In [Equation 2], V is an operating voltage magnitude, and β is a proportional constant. The unit of operating voltage magnitude is Volts, and the unit of proportional constant β is Volts/μm. For example, the proportional constant β may be about 1 to 5.

The width of the first buffer area BR1 in the second direction D2 may decrease toward the first direction D1. Meanwhile, the width of the second buffer area BR2 in the second direction D2 may increase toward the first direction D1. Each of the maximum widths of the first buffer area BR1 and the second buffer area BR2 in the second direction D2 may be substantially the same as the first width W1. For example, the first buffer area BR1 and the second buffer area BR2 may have a symmetrical shape with the emission area LER interposed therebetween. The minimum width of each of the first buffer area BR1 and the second buffer area BR2 in the second direction D2 may be substantially the same as the width of the emission area LER in the second direction D2 (i.e., the second width W2). Unlike illustrated in the drawings, profiles of corner portions of the first buffer area BR1 and the second buffer area BR2 may have a curved shape.

Also, in terms of a cross-sectional area, the heterojunction structure HS may include a first encapsulation layer N1, a graphene layer GR, and a second encapsulation layer N2 sequentially stacked in a third direction D3. The thickness of the graphene layer GR in the third direction D3 may be smaller than the thickness of the first encapsulation layer N1 and the second encapsulation layer N2 in the third direction D3. For example, the thickness of the first encapsulation layer N1 in the third direction D3 may be smaller than the thickness of the second encapsulation layer N2 in the third direction D3. For example, the length of the heterojunction structure HS in the first direction D1 may decrease toward the third direction D3. In this case, the maximum length of the first encapsulation layer N1 in the first direction D1 may be substantially the same as the first length L1. For example, the upper surface of the first portion E1a of the first electrode E1 and the upper surface of the first portion E2a of the second electrode E2 may be located at a lower level than the upper surface of the first encapsulation layer N1. In addition, as an example, the lower surface of the third portion E1c of the first electrode E1 and the upper surface of the third portion E2c of the second electrode E2 may be coplanar with the upper surface of the second encapsulation layer N2.

The photonic crystal holes PCH may pass through the first encapsulation layer N1, the graphene layer GR, and the second encapsulation layer N2. The photonic crystal holes PCH may penetrate the heterojunction structure HS to expose the side surfaces of each of the first encapsulation layer N1, the graphene layer GR, and the second encapsulation layer N2 and the upper surface of the substrate 100. The first encapsulation layer N1 and the second encapsulation layer N2 may include, for example, hexagonal boron nitride (hBN). Hexagonal boron nitride (hBN) is stable at high temperatures and may have excellent sealing effects. Accordingly, the first encapsulation layer N1 and the second encapsulation layer N2 may increase the life expectancy of the light source using the photonic crystal structure according to the inventive concept. In addition, the refractive index of hexagonal boron nitride (hBN) may be greater than that of silicon oxide or silicon nitride. Accordingly, the first encapsulation layer N1 and the second encapsulation layer N2 may reduce optical waveguiding loss on the substrate 100. At this time, the junction of each of the graphene layer GR and the first encapsulation layer N1 and the second encapsulation layer N2 may be a van der Waals heterostructure. Due to the heterogeneous bonding of the graphene layer GR and the first encapsulation layer N1 and the second encapsulation layer N2, the light source according to the inventive concept may emit light through strong light-material interaction at the bonding interface while maintaining excellent graphene properties.

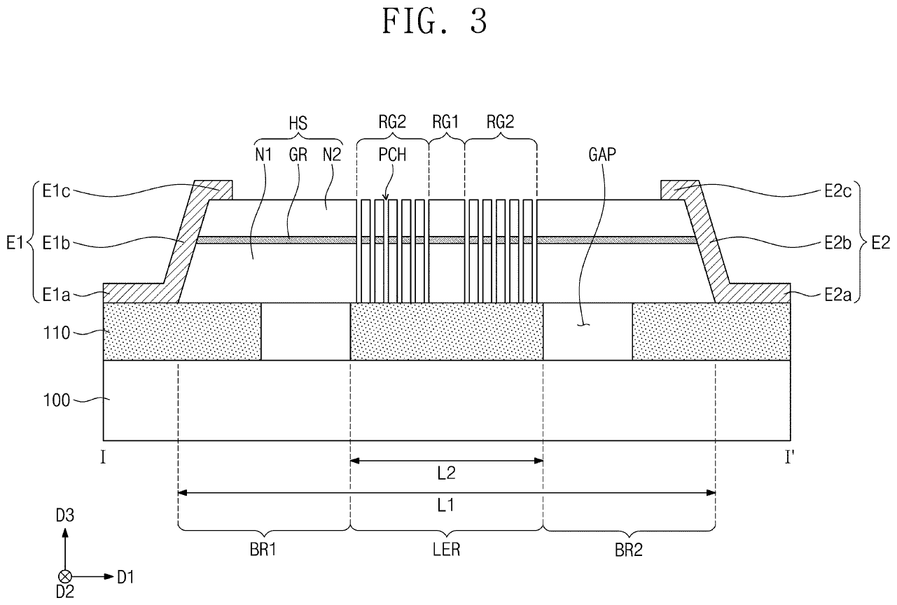

FIG. 3 is a cross-sectional view illustrating a structure of a light source using a photonic crystal structure according to an embodiment of the inventive concept, and corresponds to a cross-sectional view of FIG. 1 taken along line I-I′. Hereinafter, for convenience of description, descriptions of substantially the same matters as those described with reference to FIGS. 1 and 2 will be omitted.

Referring to FIG. 3, an optical waveguide 110 may be provided between the heterojunction structure HS and the substrate 100 or between the first electrode E1 and the second electrode E2 and the substrate 100. The optical waveguide 110 may include, for example, silicon or silicon nitride. The optical waveguide 110 may extend in the second direction D2. A plurality of optical waveguides 110 may be provided, and the plurality of optical waveguides 110 may be spaced apart from each other in the first direction D1. At least some of the optical waveguides 110 may overlap the emission area LER in the third direction D3. An empty space between the optical waveguides 110 may be defined as a gap area GAP. For example, any one of the plurality of optical waveguides 110 may overlap the entire emission area LER in the third direction D3. That is, the length of any one of the optical waveguides 110 in the first direction D1 may be determined according to the second length L2 of the emission area LER. Conversely, the second length L2 of the emission area LER may be determined according to the length in the first direction D1 of any one of the optical waveguides 110. However, unlike illustrated in the drawing, the plurality of optical waveguides 110 may overlap a part of the emission area LER, respectively, in the third direction D3. In addition, any one of the plurality of optical waveguides 110 may overlap the first area RG1 in the third direction D3. By controlling the location and number of the first area RG1, coupling between the heterojunction structure HS of the light source and the optical waveguide 110 according to the inventive concept may be improved.

In the structure of FIG. 3, when a DC bias voltage is applied to the first electrode E1 and the second electrode E2, the wavelength of the light source coupled to the optical waveguide 110 may be controlled using thermal expansion of the heterojunction structure HS by Joule heating of the graphene layer GR. In this case, the DC bias voltage may be about 5 Volts or more. In addition, in the structure of FIG. 3, an optical signal transmitted through the optical waveguide 110 may be detected or measured. More specifically, without applying a voltage to the first electrode E1 and the second electrode E2, voltage and current flowing through the graphene layer GR may be measured to detect or measure a specific wavelength of the optical signal. That is, the light source using the photonic crystal structure according to the inventive concept may be used as a photodetector.

FIG. 4a is a plan view illustrating an emission area of a light source using a photonic crystal structure according to an embodiment of the inventive concept. FIG. 4b is a graph for explaining the result of simulation of resonance frequency of a light source using a photonic crystal structure according to an embodiment of the inventive concept, and is a result according to the photonic crystal structure of FIG. 4a.

Referring to FIG. 4a, a plurality of photonic crystal holes PCH penetrating the heterojunction structure HS may be provided. For example, the first area RG1 may be provided on a center part of the upper surface of the heterojunction structure HS. The photonic crystal holes PCH may be arranged at regular intervals in the first direction D1 in the second area RG2. In addition, the photonic crystal holes PCH may be arranged in a zigzag shape while going in the second direction D2 in the second area RG2. For example, the size of the photonic crystal holes PCH may be constant. That is, the radius of each of the photonic crystal holes PCH may be the same as the first radius R1. For example, the first radius R1 may be about 50 nm to about 150 nm. Preferably, the first radius R1 may be about 90 nm to 130 nm. Also, a distance between the centers of the photonic crystal holes PCH adjacent to each other may be defined as a first lattice constant LC1. The size of the first lattice constant LC1 in the second area RG2 may be constant. For example, the first lattice constant LC1 may be about 300 nm to about 400 nm. Preferably, the first lattice constant LC1 may be about 340 nm to about 380 nm. In this case, by adjusting the values of the first radius R1 and/or the first lattice constant LC1, the resonance frequency of the light source may be controlled.

Referring to FIG. 4b, the result of simulation of the resonance frequency according to the photonic crystal structure of FIG. 4a is shown. In the graph, the horizontal axis represents the emission wavelength of the light source, and the vertical axis represents the relative value of the intensity of the emitted light. FIG. 4b shows that the lattice constant is finely adjusted due to thermal expansion according to the magnitude of the DC bias voltage, and accordingly, the resonance frequency of the light source may be controlled.

The simulation according to the photonic crystal structure of FIG. 4a shows the first to fourth resonance modes CM1, CM2, CM3, and CM4. The first to fourth resonance modes CM1, CM2, CM3, and CM4 are resonance modes when the first to fourth DC bias voltages VDC1, VDC2, VDC3, and VDC4 are applied, respectively. FIG. 4b shows that the resonance mode moves according to the magnitudes of the first to fourth DC bias voltages VDC1, VDC2, VDC3, and VDC4 (VDC1<VDC2<VDC3<VDC4).

When the first DC bias voltage VDC1 is applied, the first resonance mode CM1 may have a spectrum having a center wavelength of about 1542 nm, and when the second DC bias voltage VDC2 is applied, the second resonance mode CM2 may have a spectrum having a center wavelength of about 1546 nm. In addition, when the third DC bias voltage VDC3 is applied, the third resonance mode CM3 may have a spectrum having a center wavelength of about 1550 nm, and when the fourth DC bias voltage VDC4 is applied, the fourth resonance mode CM2 may have a spectrum having a center wavelength of about 1554 nm. In this case, the center wavelength may mean a wavelength having the greatest intensity in the spectrum of emitted light.

Meanwhile, the intensity of the first blackbody radiation spectrum BBR1 may increase according to a wavelength. The first blackbody radiation spectrum BBR1 may have a wavelength band wider than that of each of the first to fourth resonance modes CM1, CM2, CM3, and CM4, and may not have a peak. That is, the spectrum of each of the first to fourth resonance modes CM1, CM2, CM3, and CM4 may have a Gaussian distribution having a relatively high quality value as compared to the first blackbody radiation spectrum BBR1. Each of the first to fourth resonance modes CM1, CM2, CM3, and CM4 may have a quality value of about 200.

FIG. 5a is a plan view illustrating an emission area of a light source using a photonic crystal structure according to an embodiment of the inventive concept. FIG. 5b is a graph for explaining the result of simulation of resonance frequency of a light source using a photonic crystal structure according to an embodiment of the inventive concept, and is a result according to the photonic crystal structure of FIG. 5a.

Referring to FIG. 5a, a plurality of photonic crystal holes PCH penetrating the heterojunction structure HS may be provided in the emission area LER. The emission area LER may include first to third hole areas HR1, HR2, and HR3. For example, the first area RG1 may be provided inside the third hole area HR3. The outer boundary of the first hole area HR1 may be substantially the same as the boundary of the second area RG2. For example, the photonic crystal holes PCH may include first holes H1 provided inside the first hole area HR1, second holes H2 provided inside the second hole area HR2, and third holes H3 provided inside the third hole area HR3. In this case, boundaries of the first to third hole areas HR1, HR2, and HR3 may have a hexagonal shape. However, this is only an example, and the boundaries of the first to third hole areas HR1, HR2, and HR3 are not limited to a hexagonal shape and may have various shapes. For example, the first area RG1 may be provided in a center part of the upper surface of the emission area LER. More specifically, the first area RG1 may be provided in the center part of the third hole area HR3. The size of the first holes H1 may be larger than the size of the second holes H2. Also, the size of the second holes H2 may be larger than the size of the third holes H3. That is, the size of the photonic crystal holes PCH may gradually decrease as the edge of the emission area LER goes toward the center part. The distance between the centers of the photonic crystal holes PCH adjacent to each other may be defined as a second lattice constant LC2. Since the size of the photonic crystal holes PCH is not constant, the size of the second lattice constant LC2 may not be constant. For example, the second lattice constant LC2 may be about 300 nm to about 400 nm. Preferably, the second lattice constant LC2 may be about 310 nm to about 350 nm. In addition, for example, the radius of each of the first holes H1 may be about 0.2 times the second lattice constant LC2, the radius of each of the second holes H2 may be about 0.25 times the second lattice constant LC2, and the radius of each of the third holes H3 may be about 0.3 times the second lattice constant LC2. That is, the sizes of the first to third holes H1, H2, and H3 may be determined in proportion to the second lattice constant LC2. However, unlike illustrated in the drawing, four or more hole areas are provided in the emission area LER, and photonic crystal holes PCH in each of the hole areas may have different sizes.

That is, according to the photonic crystal structure of FIG. 5a, the resonance frequency of the light source may be controlled by adjusting the value of the second lattice constant LC2. In addition, a narrower emission spectrum may be obtained due to the stepwise modification of the size of the photonic crystal holes PCH. Due to the narrower emission spectrum, the quality value may increase, and as the quality value increases, the energy efficiency of the light source may increase.

Referring to FIG. 5b, a result of simulation of resonance frequencies according to the photonic crystal structure of FIG. 5a is shown. In the graph, the horizontal axis represents the emission wavelength of the light source, and the vertical axis represents the relative value of the intensity of the emitted light. FIG. 5b shows that the lattice constant is finely adjusted due to thermal expansion according to the magnitude of the DC bias voltage, and accordingly, the resonance frequency of the light source may be controlled.

The simulation according to the photonic crystal structure of FIG. 5a shows fifth to eighth resonance modes CM5, CM6, CM7, and CM8. The fifth to eighth resonance modes CM5, CM6, CM7, and CM8 are resonance modes when the fifth to eighth DC bias voltages VDC5, VDC6, VDC7, and VDC8 are applied, respectively. 5b shows that the resonance mode moves according to the magnitudes of the fifth to eighth DC bias voltages VDC5, VDC6, VDC7, and VDC8 (VDC5<VDC6<VDC7<VDC8).

When the fifth DC bias voltage VDC5 is applied, the fifth resonance mode CM5 may have a spectrum having a center wavelength of about 1542 nm, and when the sixth DC bias voltage VDC6 is applied, the sixth resonance mode CM6 may have a spectrum having a center wavelength of about 1546 nm. In addition, when the seventh DC bias voltage VDC7 is applied, the seventh resonance mode CM7 may have a spectrum having a center wavelength of about 1550 nm, and when the eighth DC bias voltage VDC8 is applied, the eighth resonance mode CM8 may have a spectrum having about 1554 nm as a center wavelength. In this case, the center wavelength may mean a wavelength having the greatest intensity in the spectrum of emitted light.

Meanwhile, the intensity of the second blackbody radiation spectrum BBR2 may increase according to a wavelength. The second blackbody radiation spectrum BBR2 may have a wavelength band wider than that of each of the fifth to eighth resonance modes CM5, CM6, CM7, and CM8, and may not have a peak. That is, the spectrum of each of the fifth to eighth resonance modes CM5, CM6, CM7, and CM8 may have a Gaussian distribution having a relatively high quality value as compared to the second blackbody radiation spectrum BBR2. Each of the fifth to eighth resonance modes CM5, CM6, CM7, and CM8 may have a quality value of about 1385. Compared with the resonance mode according to the photonic crystal structure of FIG. 4a, the resonance mode according to the photonic crystal structure of FIG. 5a may have a higher quality value.

In the above, embodiments of the inventive concept have been described with reference to the accompanying drawings, and those of ordinary skill in the art to which the inventive concept pertains will be able to understand that the inventive concept may be implemented in other specific forms without changing the technical spirit or essential features. Therefore, it should be understood that the embodiments described above are illustrative and non-limiting in all respects.

1. A light source using a photonic crystal structure comprising:
a substrate;
a heterojunction structure including a first encapsulation layer, a graphene layer, and a second encapsulation layer sequentially stacked on the substrate;
photonic crystal holes vertically penetrating the first encapsulation layer, the graphene layer, and the second encapsulation layer; and
first and second electrodes respectively connected to both end portions of the heterojunction structure,
wherein the heterojunction structure comprises buffer areas contacting the first and second electrodes, respectively, and emission areas between the buffer areas,
wherein the photonic crystal holes are provided in the emission area,
wherein a width of the emission area is smaller than widths of the buffer areas.

2. The light source of claim 1, wherein the first encapsulation layer and the second encapsulation layer comprise hexagonal boron nitride (hBN),
wherein a junction of each of the first encapsulation layer and the second encapsulation layer and the graphene layer is a van der Waals heterojunction.

3. The light source of claim 1, further comprising a plurality of optical waveguides provided between the substrate and the heterojunction structure,
wherein the optical waveguides are spaced apart from each other.

4. The light source of claim 3, wherein the optical waveguides comprise silicon or silicon nitride.

5. The light source of claim 3, wherein at least some of the optical waveguides vertically overlap the emission area.

6. The light source of claim 1, wherein the photonic crystal holes have a constant radius,
wherein a distance between centers of the photonic crystal holes adjacent to each other is defined as a first lattice constant,
wherein the first lattice constant is constant in the emission area.

7. The light source of claim 6, wherein the radius of the photonic crystal holes is 50 nm to 150 nm,
wherein the first lattice constant is 300 nm to 400 nm.

8. The light source of claim 1, wherein the emission area comprises hole areas having a hexagonal boundary,
wherein the photonic crystal holes have different sizes in each of the hole areas.

9. The light source of claim 8, wherein a size of the photonic crystal holes decreases from an edge of the emission area toward a center of the emission area.

10. The light source of claim 8, wherein a distance between centers of the photonic crystal holes adjacent to each other is defined as a second lattice constant,
wherein the second lattice constant is 300 nm to 400 nm,
wherein radii of the photonic crystal holes are determined in proportion to the second lattice constant.

11. The light source of claim 1, wherein a direction in which the first electrode and the second electrode are spaced apart from each other is defined as a first direction, and a direction perpendicular to the first direction is defined as a second direction,
wherein an operating voltage of the light source is proportional to a length of the emission area in the first direction,
wherein an operating current of the light source is proportional to a width of the emission area in the second direction.

12. A light source comprising:
a substrate;
a heterojunction structure including a first encapsulation layer, a graphene layer, and a second encapsulation layer sequentially stacked on the substrate;
photonic crystal holes vertically penetrating the first encapsulation layer, the graphene layer, and the second encapsulation layer; and
first and second electrodes respectively connected to both end portions of the heterojunction structure,
wherein the heterojunction structure comprises a first area in which the photonic crystal holes are not provided and a second area surrounding the first area, the second area in which the photonic crystal holes are regularly arranged.

13. The light source of claim 12, wherein the heterojunction structure further comprises buffer areas between the second area and the first electrode and between the second area and the second electrode.

14. The light source of claim 12, wherein a size of the photonic crystal holes decreases from the first area toward an edge of the second area.

15. The light source of claim 14, wherein the first area is located in a center of an upper surface of the heterojunction structure.

16. The light source of claim 12, further comprising a plurality of optical waveguides provided between the substrate and the heterojunction structure,
wherein the optical waveguides are spaced apart from each other,
wherein the first area vertically overlaps at least one of the optical waveguides.

17. The light source of claim 12, wherein each of the first electrode and the second electrode is a source electrode or a drain electrode,
wherein a pulse voltage or a DC bias voltage is applied to the first electrode and the second electrode.

18. The light source of claim 17, wherein a degree of thermal expansion is adjusted according to an applied magnitude of the DC bias voltage, and a resonance frequency is controlled.

19. The light source of claim 12, wherein a resonance frequency is controlled by adjusting a size and interval of the photonic crystal holes.
